(19) United States
(12) Patent Application Publication
(10) Pub. No.: US 2008/0176359 A1
(43) Pub. Date: Jul. 24, 2008

(54) Method For Manufacturing Of Electronics Package

(75) Inventors: Petri Molkkari, Tampere (FI); Pauliina Mansikkamaki, Hameenkyro (FI); Matti Mantysalo, Tampere (FI); Jani Miettinen, Jyvinkaa (FI); Jani Valtanen, Tampere (FI)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation, Espoo (FI)

(21) Appl. No.: 11/624,498

(22) Filed: Jan. 18, 2007

(51) Int. Cl. H01L 21/00; H01L 21/3205

(52) U.S. Cl. 438/110; 438/106; 438/118; 257/E23.018; 257/E21.499

(57) ABSTRACT

A method for manufacturing an electronics package is provided in which a carrier is provided, at least one electronic component is placed on the carrier and a base layer is then deposited on the electronic component(s). The base layer may include a dielectric layer binding the electronic component(s) to the carrier and providing an adhesive surface for further layers. Alternatively, the base layer may include an electrically conductive layer binding the electronic component(s) to the carrier and providing electromagnetic shielding for the electronic component(s) and an adhesive surface for further layers. A corresponding shield and a computer-readable medium for storing instructions for instructing a computer to perform the manufacturing method are also provided.

Embodiments of the invention relate in general to the manufacturing of electronics packages, and in particular to the provision of electronics packages with improved electromagnetic shielding, adhesion and fixation of components.

### BACKGROUND

Electromagnetic shielding is used in electronic devices to shield electromagnetic interferences from sensitive electronic devices or circuits, or vice versa. An example of such electronic circuits is a Wireless Local Area Network WLAN transceiver or cellular RF transceiver. To achieve the shielding, the electromagnetic interferences are shielded by providing an electrically conductive enclosure around the device or circuit to be protected.

Conventionally electromagnetic shielding is performed by providing casings or “cans” of conductive material around the circuits to be protected. In the production of electronic devices these cans must be arranged on the components to be protected and then affixed thereto, e.g. by soldering.

Such metal shielding cans are relatively expensive, need to be mounted in an additional process step in manufacturing, substantially increase the weight of the completed electronic package and also may cause thermal problems, as there may always be a certain amount of air trapped between the component and the shielding can which causes an unwished thermal isolation. It can therefore be required to provide apertures in the shielding for removing heat from electronic components, which in turn reduces the shielding efficiency.

The mounting is time-expensive and can thus slow down the production process. In case of soldering or gluing the conventional mounting of a shielding can also entail severe environmental issues due to the resulting waste and residues of hazardous substances used. In small electronic devices there can also be issues with respect to the space needed inside the electronic device for accommodating the shielding can. Similarly, in order to be able to accommodate spacious shielding cans in a device with given limited interior space it may be required to save space by restricting the available space for other components, which is apparently undesirable.

Conductive and dielectric layers require good adhesion to other layers. This requirement limits the materials that may be used for such layers. Some manufacturing processes require high temperatures, which causes problems with respect to the durability of mold materials. High temperature resistant mold materials are generally silicone-based. A few silicone-based materials show good adhesion to other materials before curing. However, typically most materials show a poor adhesion on silicone-based materials, and vice versa, at least when the silicone-based material has been cured. Therefore it is impossible to manufacture subsequent layers on top of such silicone-based materials or to mold layers with silicone-based materials. Another problem is that components are sometimes displaced during shipping or carrying between different process phases, which is apparently disadvantageous.

### SUMMARY OF THE INVENTION

According to an aspect of the present invention a method for manufacturing an electronics package is provided, comprising:
providing a carrier;
placing at least one electronic component on said carrier; and
depositing a base layer on said at least one electronic component, said base layer comprising a dielectric layer binding said at least one electronic component to said carrier and providing an adhesive surface for further layers.

The dielectric layer serves as a kind of adhesive layer and/or bonding agent for subsequently applied layers or molds. It ensures good adhesive properties for further layers and binds the electronic components in place, at least during manufacturing, such that moving the package is possible without displacing components.

According to an exemplary embodiment said base layer is deposited using one of:
inkjet printing; and
maskless mesoscale material deposition, M3D.

According to an exemplary embodiment depositing said base layer further comprises depositing an electrically conductive layer providing an electromagnetic shielding for said at least one electronic component.

This embodiment permits to manufacture electronics packages having good electromagnetic shielding, taking up minimal space, and which show good thermal properties with respect to heat dissipation. Also the weight of the electronics package can be kept low in this manner. In case there are more than one electronic component the shielding can be applied to one or more thereof. It is to be noted that the base layer may be applied in a single step, when material depositing methods are used that allow for a local change in the applied material (e.g. inkjet printing) during the application, such that dielectric layer and conductive layer can be applied in one step.

However, embodiments of the invention also include forming the base layer in multiple steps, if necessary. For example it is possible to first apply the dielectric layer and not depositing dielectric material where the conductive shield is to be located, and then applying the conductive layer. Or it is possible to deposit the dielectric material covering the whole surface, then removing the parts where the conductive layer is to be located (e.g. by using laser removal, etching etc.) and then applying the conductive layer, such that the “cutout” areas in the dielectric layer are filled.

According to an exemplary embodiment the method further comprises:
removing part of said dielectric layer prior to deposition of said electrically conductive layer.

This embodiment allows removing the dielectric layer e.g. at the edge of an electronic component, such that the electromagnetic shield is directly connected to the carrier and thus better surrounds the electronic component.

According to an exemplary embodiment the method further comprises:
molding said electronics package.

Due to the previously applied dielectric layer even molding materials that would normally not show good adhesion and could thus not be used may be used in embodiments of the present invention. That is, the previously applied dielectric layer acts as a kind of primer or tie layer.

According to an exemplary embodiment at least two electronic components are placed on the carrier, and the method further comprises:
removing the carrier; and
depositing a conductive circuit pattern connecting said at least two electronic components.

According to an exemplary embodiment said conductive circuit pattern is deposited using one of:
inkjet printing; and
maskless mesoscale material deposition, M3D.

According to an exemplary embodiment the method further comprises:
curing said electronics package.

According to a second aspect of the invention a method for manufacturing an electronics package is provided, comprising:
providing a carrier;
placing at least one electronic component on said carrier; and
depositing a base layer on said at least one electronic component, said base layer comprising a electrically conductive layer binding said at least one electronic component to said carrier, providing an electromagnetic shielding for said at least one electronic component and an adhesive surface for further layers.

According to an exemplary embodiment said base layer is deposited using one of:
inkjet printing; and
maskless mesoscale material deposition, M3D.

According to an exemplary embodiment depositing said base layer comprises depositing a dielectric layer.

According to an exemplary embodiment the method further comprises:
molding said electronics package.

According to an exemplary embodiment at least two electronic components are placed on the carrier, and the method further comprises:
removing said carrier; and
depositing a conductive circuit pattern connecting said at least two electronic components.

According to an exemplary embodiment said conductive circuit pattern is deposited using one of:
inkjet printing; and
maskless mesoscale material deposition, M3D.

According to an exemplary embodiment the method further comprises:
curing said electronics package.

According to another aspect a computer-readable medium is provided that is storing instructions for instructing a computer to perform the steps of the above described method.

According to yet another aspect of the invention a shield is provided, deposited as a layer on an electronic component placed on a carrier, wherein said shield binds said component to said carrier and provides an adhesive surface for layers deposited on top of said shield.

According to an exemplary embodiment said shield is cured with said carrier and said component.

According to an exemplary embodiment said shield is deposited by one of:
inkjet printing; and
maskless mesoscale material deposition, M3D.

According to still another aspect of the invention a usage of a deposited layer for binding an electronic component to a carrier and providing an adhesive surface for layers deposited on top of said shielding layer is provided.

According to an exemplary embodiment said layer is deposited by one of:
inkjet printing; and
maskless mesoscale material deposition, M3D.

According to an exemplary embodiment said layer is one of:
an electrically conductive layer; and
a dielectric layer.

### BRIEF DESCRIPTION OF THE DRAWINGS

The invention can be more fully understood by the following detailed description of exemplary embodiments, when also referring to the drawings, which are provided in an exemplary manner only and are not intended to limit the invention to any particular embodiment illustrated therein. In the drawings

FIG. 1 shows stage 1 of an embodiment of the method of the present invention;

FIG. 2 shows stage 2 of an embodiment of the method of the present invention;

FIG. 3 shows stage 3 of an embodiment of the method of the present invention;

FIG. 4 shows stage 4 of an embodiment of the method of the present invention;

FIG. 5 shows stage 5 of an embodiment of the method of the present invention;

FIG. 6a shows the stage prior to removal of the carrier in an embodiment of a method of the invention, in a cross section view;

FIG. 6b shows the situation depicted in FIG. 6a, in a plan view from below; and

FIG. 7 shows the situation, in a plan view from below, of a stage of the inventive method after removal of the carrier and after manufacturing of conductive circuit tracks.

### DETAILED DESCRIPTION OF THE INVENTION

It is to be noted that the following description of exemplary embodiments will focus on a particular deposition technique, that is, deposition of layers by inkjet printing. However, the invention is not restricted to inkjet printing but also includes applying layers by any other suitable deposition method such as maskless mesoscale material deposition, M3D.

Furthermore it will be appreciated that common steps that do not constitute part of the invention themselves, such as curing of applied layers, will not be described in detail in the following. For example curing can be performed by applying heat, laser, ultra violet, UV radiation and also by chemical reaction.

Embodiments of the invention can help to improve the Electro-Magnetic Interference (EMI) properties of printed circuit modules or electronic packages, respectively. It makes possible to achieve greater integration and decreases the size of electronics packages (i.e. make them lighter, thinner and smaller with respect to the area used), allows more flexible manufacturing processes, reduces the production costs and decreases material waste.

Furthermore embodiments of the invention can help to solve problems related to adhesion and displacement of electronic components and gives a circuit designer more freedom to choose a material used for molding components and manufacturing process.

Pre-printing of the dielectric material can be used on molded modules for better adhesion and/or preprinting layer before printing a conductive layer that acts as an electromagnetic interference, EMI shield. After pre-printing of dielectric materials silicone based and other types of mold materials can also be used, which gives more freedom to the module designer. The pre-printed layer binds components in place. This allows module transportation during manufacturing process if needed, without unwished displacement of components.

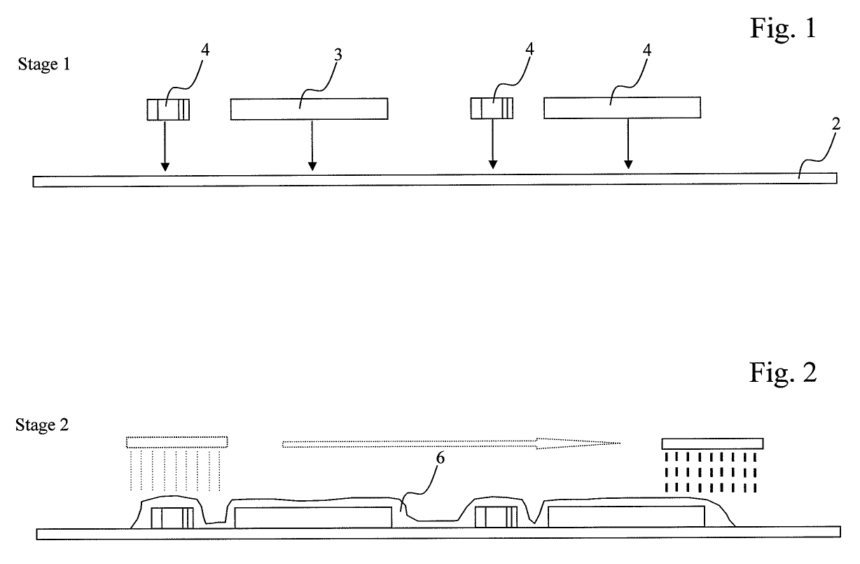

FIGS. 1 to 5 show the stages of an embodiment of the method of the invention for manufacturing an electronics package. In FIG. 1 a carrier 2 is provided, and electronic components 3, 4 are placed on the carrier 2. FIG. 2 illustrates how a dielectric layer 6 is applied to the electronic components 3, 4 via inkjet printing. The pre-printed dielectric layer 6 holds the components 3, 4 in place and thus protects them from displacement which might occur due to moving of the package. It also provides a good adhesive surface for further layers, irrespective of the material used for such layers. The dielectric layer serves as an adhesive surface for printed layers. It also binds components in place before and during a subsequent molding process.

It is to be noted that a kind of “tilting” of the inkjet print head (or the carrier in relation to the printing head) may be desirable to apply vertical portions of any applied layer. This does not necessarily apply to other deposition methods that can be used with the invention.

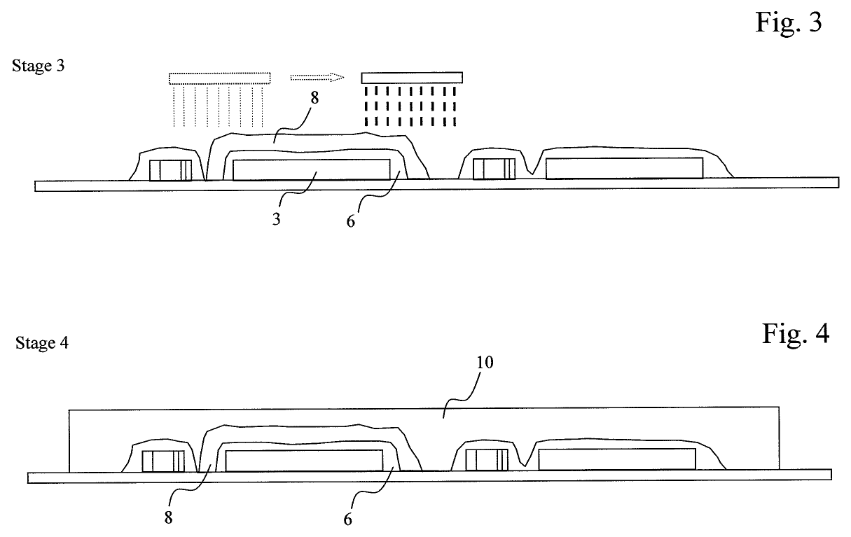

In FIG. 3 it is illustrated how an electromagnetic shielding is provided covering the electronic component 3. Again using inkjet printing a conductive layer 8 is applied to the component 3. Depending on the application it is possible to leave “cutouts” or free areas in the printed dielectric layer so that the conductive layer contacts the carrier upon deposition thereof. In this manner an improved shielding can be achieved. However, according to embodiments of the invention it is also possible to remove the dielectric material after applying a dielectric layer without holes, e.g. using laser, etching etc.

Depending on the method used for depositing the base layer comprising the dielectric and/or the conductive layer can be manufactured in a single or in multiple steps. Using inkjet technology it will usually be possible to change the material supplied to the print head during the application step, by supplying conductive material when parts are covered that shall be shielded, and dielectric material otherwise, during a continuous inkjet depositing step. Other methods to be used in the invention, e.g. mesoscale material deposition etc., may require the removal of parts of the dielectric layer before applying the conductive layer, e.g. using laser or etching.

The conductive layer 8 forms a conductive enclosure of component 3. This shielding can be implemented thinner than conventional shielding, thus saving material. Also it provides a tight fitting “can” which can provide for dissipation of heat generated within the component 3, without the need to provide ventilation holes or like. No air can be trapped in the shielding can 8 which could disturb the thermal contact between the component 3 and the shielding. Good thermal and electromagnetic properties are thus achieved.

In FIG. 4 it is shown that the electronic components 3, 4 are molded. Due to the use of the pre-printed dielectric layer 6 a good adhesion for the mold material can be achieved. This allows a greater flexibility in choosing the molding material than with conventional approaches. The improved adhesion even permits the use of silicone based materials which conventionally do adhere poorly on other materials or, vice versa, on which other materials do adhere poorly.

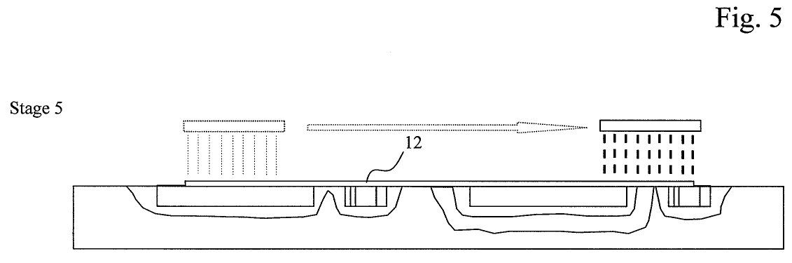

FIG. 5 illustrates a further step in the method of one embodiment of the invention. Depending on the actual production situation it may be required to rotate the electronics packaging such that the carrier side faces upwards. The carrier is removed and an electronic circuit pattern 10 connecting the electronic components 3, 4 is applied onto the now exposed underside of the electronic components, again using inkjet printing. The pattern 10 can include a section completing the shielding of component 3 on its underside, that is, for completely shielding the section of component 3 that was previously covered by the carrier.

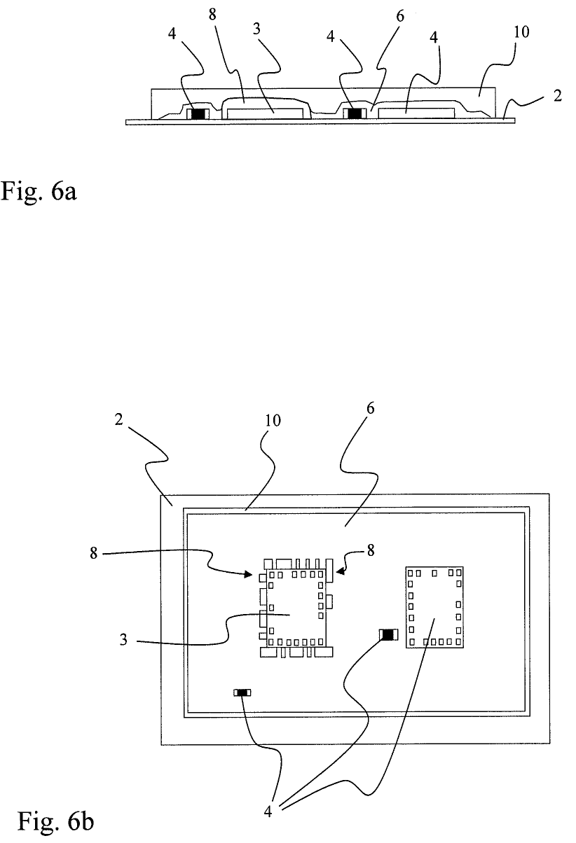

FIGS. 6a and 6b illustrate the inventive method in the stage prior to removal of the carrier. FIG. 6a is a cross section view of the molded electronics package or module before the carrier is removed. On the carrier 2 there are electronic components 3, 4, wherein only component 3 is to be electromagnetically shielded. All components 4 are covered by a dielectric layer 6, while the component 3 to be shielded is covered by a conductive layer 8. It is to be noted that the conductive layer 8 does not necessarily contact the carrier 2 over its whole edge-wise extension. Depending on the actual situation it is possible to have areas in which there is no contact between carrier 2 and conductive layer 8. This can better be seen in FIG. 6b. Sections of the conductive layer 8 contacting the carrier 2 can be achieved by leaving out parts of the dielectric layer, or by removing the respective parts after application of the dielectric layer, by any suitable method like laser, etching etc.

FIG. 6b shows the same situation as in FIG. 6a, however in a plan view from below, that is, from the carrier side. Identical parts as in FIG. 6a have the same reference signs, so reference is also made to the description of that figure. As can be seen here, there are only certain sections where the conductive layer 8 contacts the carrier, while in the remaining parts along the edge of electronic component 3 there is a dielectric layer 6 between the corresponding part of conductive layer 8 and carrier 2. Such “cutouts” in the shielding that are constituted by conductive layer 8 may be provided in order to facilitate application of the conductive tracks or circuit tracks, respectively.

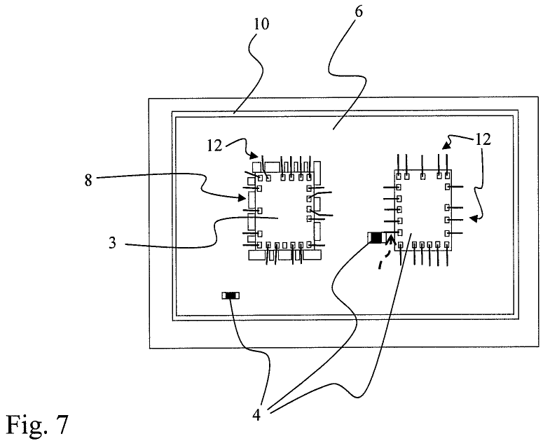

FIG. 7 illustrates, again in a plan view from below as in FIG. 6b, the electronic module of FIGS. 6a and 6b after removal of the carrier. Furthermore conductive tracks 12 forming a circuit pattern have been applied here. Such tracks 12 can already connect electronic components, as can be seen on the right of the figure (indicated by the dashed arrow), or be left “open” to connect other components and/or layers to be manufactured later on. The tracks 12 are used to constitute connections between the contact pads/pins etc. of electronic components, to form an electronic circuit pattern.

To summarize, pre-printing of a dielectric layer according to an embodiment of the invention allows using a wide variety of mold materials, even such as silicone-based materials, in the production of electronics packages or modules, respectively. This gives more freedom to a module designer. The pre-printing layer also binds electronic components in place. This allows module transportation during the manufacturing process if needed. By pre-printing the dielectric layer before molding, a good surface for subsequent layers can be obtained. Further layers may be manufactured separately and attached afterwards or layers may be manufactured directly on the module.

By providing an electromagnetic shielding with a method of one embodiment of the invention, waste of materials can be avoided. The resulting electronic modules can be designed occupying less space and also lighter, due to thinner shielding enclosures. A better heat dissipation is also achieved, as there is direct thermal contact between the shielding and the shielded electronic component.

While the foregoing specification is provided to draw attention to those features of the invention believed to be of particular importance it should be understood that protection is claimed with respect to any patentable feature or combination of features referred to and/or shown in the drawings, whether or not particular emphasis has been put thereon. It should be appreciated that those skilled in the art, upon consideration of the present disclosure, may make modifications and/or improvements on the method hereof and yet remain within the scope and spirit of the invention as set forth in the appended claims.

1. Method for manufacturing an electronics package, comprising:
providing a carrier;
placing at least one electronic component on said carrier; and
depositing a base layer on said at least one electronic component, said base layer comprising a dielectric layer binding said at least one electronic component to said carrier and providing an adhesive surface for further layers.

2. Method according to claim 1, wherein said base layer is deposited using one of:
inkjet printing; and
maskless mesoscale material deposition, M3D.

3. Method according to claim 1, wherein depositing said base layer comprises depositing an electrically conductive layer covering said at least one electronic component for providing an electromagnetic shielding.

4. Method according to claim 3, further comprising:
removing part of said dielectric layer prior to deposition of said electrically conductive layer.

5. Method according to claim 1, further comprising:
molding said electronics package.

6. Method according to claim 5, wherein at least two electronic components are placed on the carrier, the method further comprising:
removing said carrier; and
depositing a conductive circuit pattern connecting said at least two electronic components.

7. Method according to claim 6, wherein said conductive circuit pattern is deposited using one of:
inkjet printing; and
maskless mesoscale material deposition, M3D.

8. Method according to claim 6, further comprising:
curing said electronics package.

9. Method for manufacturing an electronics package, comprising:
providing a carrier;
placing at least one electronic component on said carrier; and
depositing a base layer on said at least one electronic component, said base layer comprising a electrically conductive layer binding said at least one electronic component to said carrier, providing an electromagnetic shielding for said at least one electronic component and an adhesive surface for further layers.

10. Method according to claim 9, wherein said base layer is deposited using one of:
inkjet printing; and
maskless mesoscale material deposition, M3D.

11. Method according to claim 9, wherein depositing said base layer comprises depositing a dielectric layer.

12. Method according to claim 9, further comprising:
molding said electronics package.

13. Method according to claim 12, wherein at least two electronic components are placed on the carrier, the method further comprising:
removing said carrier; and
depositing a conductive circuit pattern connecting said at least two electronic components.

14. Method according to claim 13, wherein said conductive circuit pattern is deposited using one of:
inkjet printing; and
maskless mesoscale material deposition, M3D.

15. Method according to claim 13, further comprising:
curing said electronics package.

16. Computer-readable medium storing instructions for instructing a computer to perform the steps of claim 1 when run on said computer.

17. Computer-readable medium storing instructions for instructing a computer to perform the steps of claim 9 when run on said computer.

18. Shield, deposited as a layer on an electronic component placed on a carrier, wherein said shield binds said component to said carrier and provides an adhesive surface for layers deposited on top of said shield.

19. Shield according to claim 18, wherein said shield is cured with said carrier and said component.

20. Shield according to claim 18, wherein said shield is deposited by one of:
inkjet printing; and
maskless mesoscale material deposition, M3D.

21. Usage of a deposited layer for binding an electronic component to a carrier and providing an adhesive surface for layers deposited on top of said shielding layer.

22. Usage according to claim 21, wherein said layer is deposited by one of:
inkjet printing; and
maskless mesoscale material deposition, M3D.

23. Usage according to claim 21, wherein said layer is one of:
an electrically conductive layer; and
a dielectric layer.
